(19) United States
(12) Patent Application Publication
(10) Pub. No.: US 2024/0222567 A1
(43) Pub. Date: Jul. 4, 2024

(54) MICRO LIGHT-EMITTING ASSEMBLY, MICRO LIGHT-EMITTING DIODE ANDDISPLAY DEVICE

(71) Applicant: XIAMEN SAN'AN OPTOELECTRONICS CO., LTD., Xiamen (CN)

(72) Inventors: Chia-en LEE, Xiamen (CN); Zheng WU, Xiamen (CN); TE-LING HSIA, Xiamen (CN); Boqi ZHAN, Xiamen (CN); Xueping YE, Xiamen (CN)

(21) Appl. No.: 18/602,081

(22) Filed: Mar. 12, 2024

Related U.S. Application Data
(63) Continuation of application No. PCT/CN2021/118184, filed on Sep. 14, 2021.

(51) Int. Cl. H01L 33/44; H01L 25/16

(52) U.S. Cl. CPC H01L 33/44; H01L 25/167

(57) ABSTRACT

A micro light-emitting assembly, a micro light-emitting diode and a display device are provided, the micro light-emitting assembly at least includes: a support structure and a semiconductor layer sequence. The support structure at least includes a bridge arm structure constituted by overlapping multiple dielectric layers with different stress directions, and materials of adjacent dielectric layers are different. The bridge arm is fixed with the semiconductor layer sequence, the multiple dielectric layers with different stress directions are cross stacked to constitute the bridge arm structure, so that stress generated inside of the bridge arm can be offset, and a problem that the bridge arm structure is easy to break is solved.

### TECHNICAL FIELD

The disclosure relates to the technical field of semiconductor structures, and more particularly to a micro light-emitting assembly, a micro light-emitting diode and a display device.

### BACKGROUND

At present, a micro light-emitting diode on a carrier substrate is transferred to a receive substrate through van der Waals force, electrostatic force, or magnetic force. In general, the micro light-emitting diode is fixed through a support structure, so that the micro light-emitting diode is easy to be picked, transported and transferred from the carrier substrate to the receive substrate, and quality of the micro light-emitting diode is not affected by other internal or external factors during transferring through the support structure.

Photosensitive materials or single layer dielectric thin films are used to prepare the support structure at present, however, a size of the micro light-emitting diode is decreased, and a width of the support structure is limited accordingly, so that a structural strength of the support structure is relatively fragile. During a chip manufacturing process, a suspended structure of the micro light-emitting diode is prepared to improve a transfer yield, which usually requires a process of bonding a sacrificial layer. Therefore, during bonding the sacrificial layer, how to make the support structure temporarily fix the micro light-emitting diode without increasing difficulty of imprinting transfer during subsequent transfer has become one of current technical challenges in the industry.

### SUMMARY

In order to solve problems of the related art, the disclosure provides a micro light-emitting assembly, a micro light-emitting diode and a display device, to achieve a balance between a transfer yield when transferring micro light-emitting diodes and a bridge arm strength when bonding a sacrificial layer.

In order to solve the above problem, the disclosure provides a micro light-emitting assembly, the micro light-emitting assembly includes: a substrate providing support for chiplets, a main body with a semiconductor layer sequence (i.e., a main part of a micro light emitting diode for emitting light), and a support structure, and the semiconductor layer sequence is fixed on the substrate through the support structure.

The support structure at least includes: a first dielectric layer and a second dielectric layer. In some processes, the second dielectric layer covers a surface of the first dielectric layer. A material of the first dielectric layer is different from that of the second dielectric layer, and the first dielectric layer is disposed between the second dielectric layer and the semiconductor layer sequence, and is connected to the second dielectric layer and the main body. A gap is defined between the main body and an upper surface of the substrate. A thickness of the second dielectric layer is 1.5 to 10 times that of the first dielectric layer. In order to provide sufficient support, the thinner first dielectric layer is used to eliminate stress during process at first, which can avoid rupture of the support structure caused by stress release during bonding process. The second dielectric layer is mainly used to provide a bridge connection for chiplets and the substrate during transferring, and the thickness of the second dielectric layer is significantly larger than that of the first dielectric layer. Meanwhile, difficulty in stress regulation of the support structure is reduced by utilizing different materials of the first dielectric layer and the second dielectric layer, and differences in film-forming stresses.

In an embodiment, the material of the first dielectric layer is silicon oxide, the first dielectric layer is connected to the semiconductor layer sequence of the main body, and the material of the second dielectric layer is silicon nitride. The thickness of the first dielectric layer is in a range of 0.1 to 0.5 microns (μm), the thickness of the second dielectric layer is in a range of 0.15 to 0.3 μm, 0.3 to 0.8 μm, or 0.8 to 2 μm, and widths of the first dielectric layer and the second dielectric layer are in a range of 1 to 20 μm.

In an embodiment, the semiconductor layer sequence at least includes: a first semiconductor layer, an active layer and a second semiconductor layer. The semiconductor layer sequence includes: a first part facing away from the substrate and a second part proximate to the substrate. A projection of the first part on a horizontal plane is larger than a projection of the second part on the horizontal plane, and the support structure extends to the substrate from a bottom of the first part. The second part at least includes: the active layer and the second semiconductor layer, and a side wall of the second part is provided with at least one of the first dielectric layer and the second dielectric layer.

In an embodiment, the first part includes: a N-type semiconductor layer, and the second part includes: a N-type semiconductor layer, an active layer and a P-type semiconductor layer.

In an embodiment, the support structure includes: a fixed anchor. A material of the fixed anchor is rubber material, inorganic medium or metal. At least one of the first dielectric layer and the second dielectric layer is indirectly connected to the substrate through the fixed anchor.

In an embodiment, a part of the first dielectric layer is removed, the second dielectric layer is exposed from the first dielectric layer, and the main body is configured to directly or indirectly fix the semiconductor layer sequence on the substrate through the second dielectric layer.

In the embodiment, the first dielectric layer defines a groove or hole, and the second dielectric layer is exposed from the groove or the hole.

In the embodiment, the groove or the hole is defined around the semiconductor layer sequence.

In an embodiment, each of the first dielectric layer and the second dielectric layer of the support structure is a single layer.

In an embodiment, a side of the main body facing away from the substrate is provided with a coarse structure, and the coarse structure is prepared by etching.

In the embodiment, a side of the main body proximate to the substrate is provided with a third dielectric layer, and a material of the third dielectric layer includes titanium oxide. The third dielectric layer is disposed between the main body and the first dielectric layer, and the first dielectric layer and the second dielectric layer cover a side of the third dielectric layer, sequentially.

In an embodiment, the thickness of the second dielectric layer is variable, and a thickness of the second dielectric layer facing away from the main body is smaller than a thickness of the second dielectric layer below the main body.

In an embodiment, the material of the first dielectric layer at least includes a material with negative stress direction, and the material of the second dielectric layer at least includes a material with positive stress direction. For example, the first dielectric layer adopts thin silicon oxide. A film-forming stress of the silicon oxide is relatively larger than that of the silicon nitride during process, which can be used to regular stress. However, it is not advisable to set the thickness of silicon oxide too thick, and then make the second dielectric layer with thicker silicon nitride, so that a film-forming quality of the second dielectric layer is improved.

The disclosure further provides a micro light-emitting diode, and the micro light-emitting diode includes: a semiconductor layer sequence, a first electrode, a second electrode and a residual support structure.

The semiconductor layer sequence at least includes: a first semiconductor layer, a second semiconductor layer and an active layer disposed between the first semiconductor layer and the second semiconductor layer. The semiconductor layer sequence at least includes a first part and a second part. A projection of the first part on the horizontal plane is larger than a projection of the second part on the horizontal plane, the first part is disposed above the second part, and a lower surface of the first part is exposed from the second part. The second part at least includes: the active layer and the second semiconductor layer, and a side wall of the second part is provided with at least one of a first dielectric layer and a second dielectric layer.

The first electrode is electrically connected to the first semiconductor layer, and the second electrode is electrically connected to the second semiconductor layer.

The residual support structure at least includes the first dielectric layer and the second dielectric layer. A material of the first dielectric layer is different from that of the second dielectric layer, the first dielectric layer is disposed between the second dielectric layer and the semiconductor layer sequence, and a thickness of the second dielectric layer is 1.5 to 10 times that of the first dielectric layer.

In an embodiment, the second part at least includes the active layer and the second semiconductor layer. The side wall of the second part is provided with at least one of the first dielectric layer and the second dielectric layer. The micro light-emitting diode is protected through retracting the second part and using at least one of the first dielectric layer and the second dielectric layer, so as to prevent short circuit and other anomalies.

In an embodiment, a surface on a side of the first semiconductor layer facing away from the second semiconductor layer is provided with a coarse structure, and the coarse structure is made by etching.

In an embodiment, a surface on a side of the second semiconductor layer is provided with a third dielectric layer. A material of the third dielectric layer includes titanium oxide, the third dielectric layer is disposed between the semiconductor layer sequence and the first dielectric layer, and the first dielectric layer and the second dielectric layer cover a side of the third dielectric layer, sequentially.

In the embodiment, at the side covering the third dielectric layer, a total thickness of the first dielectric layer and the second dielectric layer is not smaller than 0.5 μm, and a distance between the third dielectric layer and an edge of the first dielectric layer is not smaller than 0.5 μm.

In an embodiment, the material of the first dielectric layer is the silicon oxide, and the material of the second dielectric layer is the silicon nitride. The thickness of the first dielectric layer is in a range of 0.1 to 0.5 μm, the thickness of the second dielectric layer is in a range of 0.15 to 0.3 μm, 0.3 to 0.8 μm, or 0.8 to 2 μm, a width of the first dielectric layer is in a range of 1 to 20 μm, and a width of the second dielectric layer is in a range of 1 to 20 μm.

In an embodiment, a part of the second dielectric layer is removed, and the first dielectric layer is exposed from the second dielectric layer.

In the embodiment, the second dielectric layer defines a groove or hole, and the first dielectric layer is exposed from the groove or the hole.

In the embodiment, the groove or the hole is defined around the semiconductor layer sequence.

In an embodiment, each of the first dielectric layer and the second dielectric layer of the support structure is a single dielectric layer.

The disclosure further provides a display device, and the display device includes: a bracket, a circuit board and the micro light-emitting diode in the above technical solutions.

Beneficial effects of the disclosure are as follows.

1. A contact stress between the second dielectric layer and the semiconductor layer sequence is adjusted by using the first dielectric layer which is disposed on the main body and is thinner than the second dielectric layer as a stress control layer.

2. The thickness of the bridge connection part has a great effect on the transfer yield actually, and through removing the first dielectric layer of the bridge connection part between the support structure and the semiconductor layer sequence, a goal of balancing the transfer yield is achieved.

Other beneficial effects of the disclosure will be gradually described in conjunction with embodiments.

### BRIEF DESCRIPTION OF DRAWINGS

Drawings are used to provide a further description for the disclosure, and form a part of the specification. The drawings are used to describe the disclosure with embodiments of the disclosure, and do not constitute a limitation of the disclosure. In addition, data of the drawings is a descriptive summary, not drawn to scale.

FIG. 1a illustrates a schematic sectional structural diagram of a micro light-emitting assembly according to an embodiment 1 of the disclosure.

FIG. 1b illustrates a schematic structural diagram from a top-down perspective of the micro light-emitting assembly according to the embodiment 1 of the disclosure.

FIG. 1c illustrates a schematic structural diagram from a down-top perspective of the micro light-emitting assembly according to the embodiment 1 of the disclosure.

FIG. 2 illustrates a schematic sectional structural diagram of a micro light-emitting assembly according to an embodiment 2 of the disclosure.

FIG. 3 illustrates a schematic sectional structural diagram of a micro light-emitting assembly according to an embodiment 3 of the disclosure.

FIG. 4a illustrates a schematic sectional structural diagram of a micro light-emitting assembly according to an embodiment 4 of the disclosure.

FIG. 4b illustrates a schematic structural diagram from a top-down perspective of the micro light-emitting assembly according to the embodiment 4 of the disclosure.

FIG. 5a illustrates a schematic sectional structural diagram of a micro light-emitting assembly according to an embodiment 5 of the disclosure.

FIG. 5b illustrates a schematic structural diagram from a top-down perspective of the micro light-emitting assembly according to the embodiment 5 of the disclosure.

FIG. 6a illustrates a schematic sectional structural diagram of a micro light-emitting assembly according to an embodiment 6 of the disclosure.

FIG. 6b illustrates a schematic structural diagram from a top-down perspective of the micro light-emitting assembly according to the embodiment 6 of the disclosure.

FIG. 7a illustrates a schematic sectional structural diagram of a micro light-emitting assembly according to an embodiment 7 of the disclosure.

FIG. 7b illustrates a schematic structural diagram from a top-down perspective of the micro light-emitting assembly according to the embodiment 7 of the disclosure.

FIG. 8a illustrates a schematic sectional structural diagram of a micro light-emitting assembly according to an embodiment 8 of the disclosure.

FIG. 8b illustrates a schematic structural diagram from a top-down perspective of the micro light-emitting assembly according to the embodiment 8 of the disclosure.

FIG. 9a illustrates a schematic sectional structural diagram of a micro light-emitting assembly according to an embodiment 9 of the disclosure.

FIG. 9b illustrates a schematic structural diagram from a top-down perspective of the micro light-emitting assembly according to the embodiment 9 of the disclosure.

FIGS. 10 to 14 illustrate schematic structural diagrams of a micro light-emitting diode according to an embodiment 10 of the disclosure.

FIG. 15a illustrates a schematic sectional structural diagram of a micro light-emitting diode according to an embodiment 11 of the disclosure.

FIG. 15b illustrates a schematic structural diagram from a down-top perspective of the micro light-emitting diode according to the embodiment 11 of the disclosure.

FIG. 16a illustrates a schematic sectional structural diagram of a micro light-emitting diode according to an embodiment 12 of the disclosure.

FIG. 16b illustrates a schematic structural diagram from a down-top perspective of the micro light-emitting diode according to the embodiment 12 of the disclosure.

FIG. 17a illustrates a schematic sectional structural diagram of the micro light-emitting diode according to some implementation methods in the embodiment 12 of the disclosure.

FIG. 17b illustrates a schematic structural diagram from a down-top perspective of the micro light-emitting diode according to some implementation methods in the embodiment 12 of the disclosure.

FIG. 18a illustrates a schematic sectional structural diagram of a micro light-emitting diode according to an embodiment 13 of the disclosure.

FIG. 18b illustrates a schematic structural diagram from a top-down perspective of the micro light-emitting diode according to the embodiment 13 of the disclosure.

FIG. 19 illustrates a schematic structural diagram from a top-down perspective of the micro light-emitting diode according to some implementation methods in the embodiment 13 of the disclosure.

FIG. 20 illustrates a schematic sectional structural diagram of a display device according to an embodiment 14 of the disclosure.

### LIST OF REFERENCE NUMBERS

100—main body; 101—first part; 102—second part; 111—first semiconductor layer; 112—second semiconductor layer; 113-active layer; 121—first electrode; 122—second electrode; 200—support structure; 200′—residual support structure; 201—fixed anchor; 210—first dielectric layer; 211—through groove; 220—second dielectric layer; 230—third dielectric layer; 300—substrate; 400—cavity; 500—growth substrate; 600—sacrificial bonding layer; 700—embossing; 800—bracket; 810—circuit board; A1—first platform; A2—second platform; A3—third platform; F—fracture surface.

### DETAILED DESCRIPTION OF EMBODIMENTS

In order to make purposes, technical solutions and advantages of embodiments of the disclosure clearer, the technical solutions of the embodiments of the disclosure will be clearly and completely described in conjunction with drawings in the embodiments of the disclosure below. Apparently, the described embodiments are some of the embodiments of the disclosure, not all of them. Based on the embodiments in the disclosure, all other embodiments obtained by those skilled in the art without creative work fall within a scope of protection of the disclosure.

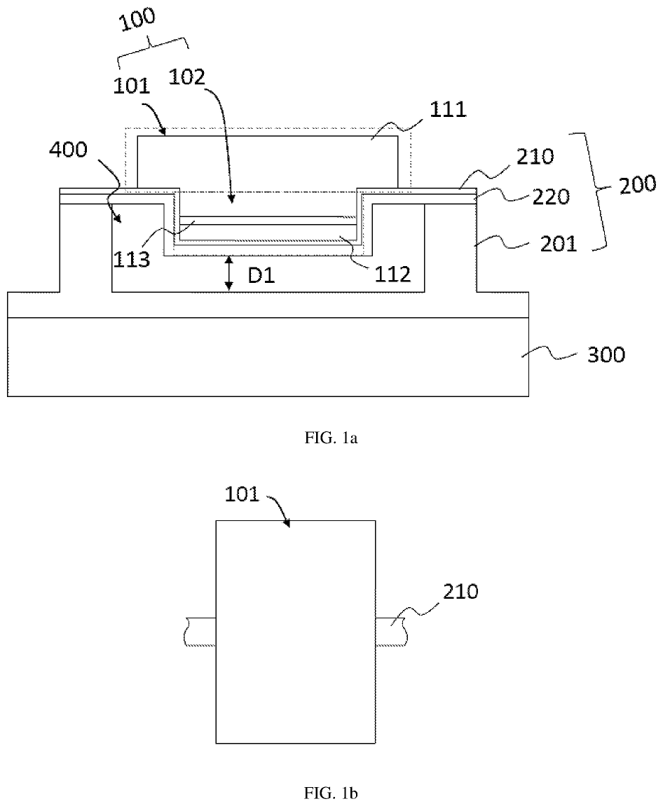

Referring to FIGS. 1a, 1b and 1c in combination, an embodiment 1 of the disclosure provides a micro light-emitting assembly, and the micro light-emitting assembly includes a main body 100 with a semiconductor layer sequence, that is a main part of a micro light emitting diode for emitting light. The main body 100 is connected to a substrate 300 through a support structure 200. The semiconductor layer sequence includes: a first semiconductor layer 111, a second semiconductor layer 112 and an active layer 113 disposed between the first semiconductor layer 111 and the second semiconductor layer 112. A material of the semiconductor layer sequence is gallium nitride system, and the disclosure mainly describes a film-forming stress between gallium-nitride-based and insulation dielectric materials, and designs a matching scheme based on an influence of surface contacts between gallium nitride and silicon oxide or silicon nitride.

In the embodiment, in a schematic sectional structural diagram, an area of a top surface of the first semiconductor layer 111 is larger than that of the second semiconductor layer 112, the area of the top surface of the first semiconductor layer 111 is larger than that of the active layer 113, and centers of the first semiconductor layer 111, the second semiconductor layer 112 and the active layer 113 basically overlap on a vertical projection plane. The main body 100 includes: a first part 101 facing away from the substrate 300 and a second part 102 proximate to the substrate 300. A projection of the first part 101 on a horizontal plane is larger than that of the second part 102 on the horizontal plane, the first part 101 is disposed above the second part 102, and the support structure 200 extends from a bottom of the first part 101 and a side of the second part 102 to the substrate 300. In the embodiment, the first part 101 includes a N-type semiconductor layer, and the second part 102 includes a N-type semiconductor layer, a P-type semiconductor layer and the active layer 113 composed of quantum wells and disposed between the N-type semiconductor layer and the P-type semiconductor layer.

An end of the support structure 200 is directly or indirectly connected to the main body 100 of the micro light-emitting assembly, and another end of the support structure 200 is directly or indirectly connected to the substrate 300. The support structure 200 at least includes: a first dielectric layer 210 and a second dielectric layer 220. A side surface of the first semiconductor layer 111 facing away from the second semiconductor layer 112 is defined as a first surface, a side surface of the second semiconductor layer 112 facing away from the first semiconductor layer 111 is defined as a second surface, and the first surface and the second surface are opposite. The first dielectric layer 210 is connected to the second surface of the semiconductor layer sequence or the main body 100, or covers the second surface of the semiconductor layer sequence or the main body 100, the second dielectric layer 220 covers a surface of the first dielectric layer 210, and at least a part of the first dielectric layer 210 is disposed between the second dielectric layer 220 and the semiconductor layer sequence. A material of the first dielectric layer 210 is different from that of the second dielectric layer 220. Stress control of a single layer material is easy limited by stress and control conditions of a film-forming device, compared to use a same material, the disclosure is easy to balance residual stress generated in the process by means of two different dielectric materials, and can generate more elastic opposite stress.

A gap is defined between the main body 100 composed of the semiconductor layer sequence and an upper surface of the substrate 300. A bottom surface of the main body 100 is further provided with a first electrode 121 electrically connected to the first semiconductor layer 111 and a second electrode 122 electrically connected to the second semiconductor layer 122, thus, a distance D1 for the reserved gap is in a range of 0.5 to 3 microns (μm). In the embodiment, the distance D1 of the reserved gap is a distance between the second dielectric layer 220 and the upper surface of the substrate 300. The gap is used to leave a downward displacement space for the micro light-emitting diode when transferring chiplets through an embossing, so as to avoid damage to the chiplets by the substrate 300 or the graphics on the substrate 300.

In the embodiment, the support structure 200 constitutes a bridge arm, and the micro light-emitting diode is suspended on the substrate 300 through the bridge arm. A cavity 400 is defined between the bridge arm and the substrate 300, and the semiconductor layer sequence of the micro light-emitting diode is disposed on an inner side or an outer side of the cavity 400. In the embodiment, the semiconductor layer sequence is disposed on the outer side of the cavity 400.

A thickness of the second dielectric layer 220 is 1.5 to 10 times that of the first dielectric layer 210. The thin first dielectric layer 210 is mainly used to eliminate stress in the process, and avoid rupture of the support structure 200 caused by stress release during the bonding process. The second dielectric layer 220 is used for a bridge connection between the core particles and the substrate 300 during transferring. The thickness of the second dielectric layer 220 is significantly larger than that of the first dielectric layer 210, the materials of the first dielectric layer 210 and the second dielectric layer 220 are different, and film-forming stresses of the first dielectric layer 210 and the second dielectric layer 220 are different, thus, stress control difficulty of the support structure 200 is decreased.

In the embodiment, each of the first dielectric layer 210 and the second dielectric layer 220 in the support structure 200 is a single layer. The material of the first dielectric layer 210 is silicon oxide, the material of the first dielectric layer 210 at least includes a material with negative stress direction, and the material of the second dielectric layer 220 at least includes a material with positive stress direction. An absolute value of unit positive stress of the second dielectric layer 220 is less than an absolute of unit negative stress of the first dielectric layer 210, which is beneficial for controlling overall stress conditions. The first dielectric layer 210 is connected to the semiconductor layer sequence of the main body 100, and the material of the second dielectric layer 220 is silicon nitride. In the embodiment, the stress of the silicon oxide is in a range of 0 to 200 megapascals (MPa), and the stress of the silicon nitride is in a range of −200 to 200 MPa.

The first dielectric layer 210 and/or the second dielectric layer 220 extend downwards along a side of the main body 100 of the micro light-emitting diode, and basically cover a bottom of the main body 100. The first electrode 121 and the second electrode 122 are exposed from the bottom of the first dielectric layer 210 and/or the second dielectric layer.

In the embodiment, the first dielectric layer 210 and/or the second dielectric layer 220 can be disposed on two sides of the main body 100, and can be also disposed on a single side of the main body 100.

In the embodiment, the support structure 200 includes: a fixed anchor 201. A material of the fixed anchor 201 is rubber material, inorganic medium or metal, specifically, the rubber material is used as the material of the fixed anchor 201. The fixed anchor 201 is directly disposed on the substrate 300, an end of the first dielectric layer 210 and/or the second dielectric layer 220 is disposed on the fixed anchor 201, and the first dielectric layer 210 and/or the second dielectric layer 220 are indirectly connected to the substrate 300 through the fixed anchor 201. In some embodiments, the fixed anchor 201 is disposed on the two sides of the main body 100.

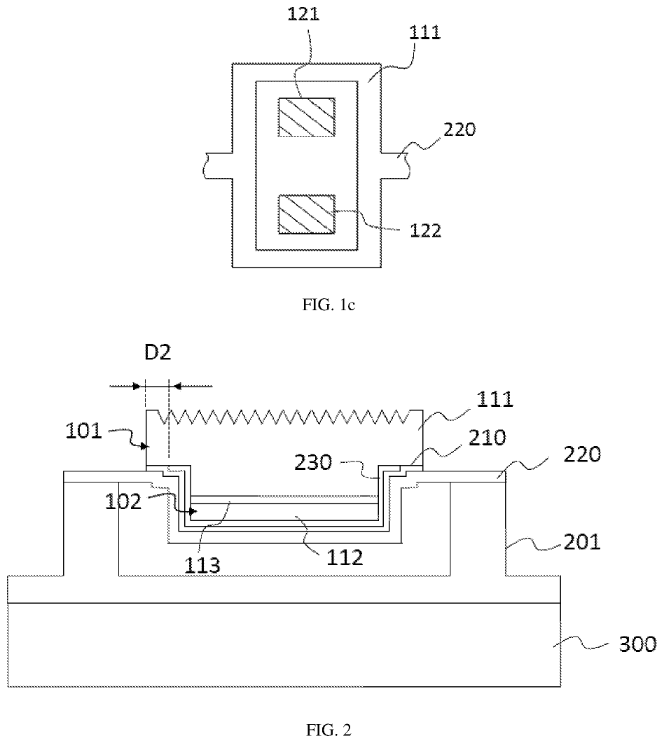

As shown in FIG. 2, in an embodiment 2 of the disclosure, the first surface has a coarse or pattern area made by etching, and the first surface can be a coarse surface entirely or partially. A third dielectric layer 230 is disposed between the main body 100 and the support structure 200. The third dielectric layer 230 can be an insulation reflective layer, for example, a distributed Bragg reflector (DBR). A material of the third dielectric layer 230 includes titanium oxide. However, the titanium oxide is easy damaged by etching during making the coarse surface. Therefore, in the embodiment, a side of the third dielectric layer 230 proximate to an edge of the main body 100 is covered by the first dielectric layer 210, so as to avoid exposing the third dielectric layer 230. The first dielectric layer 210 extends from the side of the third dielectric layer 230 to a lower surface of the first semiconductor layer 111. A distance D2 between an edge of the third dielectric layer 230 and the edge of the main body 100 is not smaller than 0.5 μm. A sufficient contact distance is reserved by the first dielectric layer 210 and/or the second dielectric layer 220, which can be also understood as that a width of a bottom of the first part 101 covered by the first dielectric layer 210 and/or the second dielectric layer 220 is not smaller than 0.5 μm. In the process, the third dielectric layer 230 is a discontinuity layer. In order to avoid complexing the stress control conditions, the first dielectric layer 210 is disposed on a side of the support structure 200 facing away from the gap, a part of the first dielectric layer 210 is removed, and the second dielectric layer 220 is exposed from the first dielectric layer 210.

In the embodiment, a part of the first dielectric layer 210 exposed from the bottom of the first semiconductor layer 111 is removed. The support structure 200 covered by the first semiconductor layer 111 includes: the first dielectric layer 210 and the second dielectric layer 220; and the exposed support structure 200 includes the second dielectric layer 220, and the exposed support structure 200 is connected to the fixed anchor 201 or extends to the substrate 300 through the second dielectric layer 220.

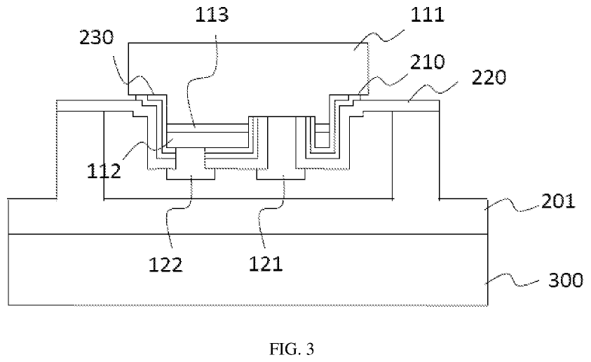

As shown in FIG. 3, in an embodiment 3 of the disclosure, the first dielectric layer 210 is further removed on the basis of the embodiment 2, that is, the first dielectric layer 210 extends along an outer edge of the main body 100, and a distance between the first dielectric layer 210 and the outer edge of the main body 100 is not larger than 0.2 μm. A fracture location of the second dielectric layer 220 is preset on the exposed part of the support structure 200, so as to control the fracture surface of the support structure 200 to be as close as possible to the main body 100, and avoid excessive residual support structure 200 that may affect product application during the process of substrate transfer by the embossing 700.

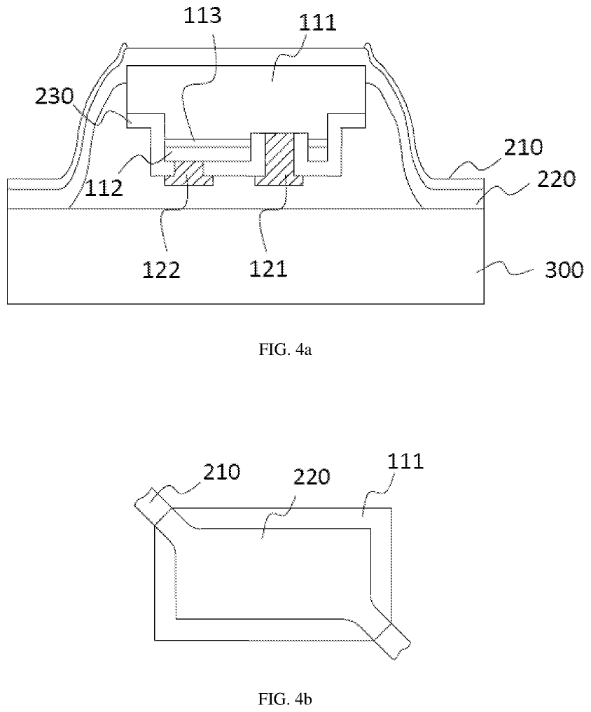

As shown in FIGS. 4a and 4b, an embodiment 4 of the disclosure provides another micro light-emitting assembly, and the micro light-emitting assembly includes: a main body 100, a support structure 200 and a substrate 300. The support structure 200 extends from a surface of the substrate 300 to a side and/or an upper surface of the main body 100. Specifically, a second dielectric layer 220 covers the upper surface of the main body 100, and a first dielectric layer 210 covers the second dielectric layer 220. At least a part of the support structure 200 on an upper surface of a micro light-emitting diode is removed, so that the second dielectric layer 220 is exposed, and the second dielectric layer 220 constitutes a platform on the surface of the main body 100. The first dielectric layer 210 between a center area of the upper surface of the micro light-emitting diode and an edge of the upper surface of the micro light-emitting diode is removed, a distance between a projection of the first dielectric layer 210 of the support structure 200 on the horizontal projection plane and the edge of the main body 100 is not larger than 0.5 μm, so as to ensure that the support structure 200 has sufficient bonding strength, and can satisfy the fracture requirement during substrate transfer.

A third dielectric layer 230 is disposed on the bottom of the main body 100, the third dielectric layer 230 can be an insulation reflective layer or an inorganic insulation layer, and a first electrode 121 and a second electrode 122 are exposed from the third dielectric layer 230.

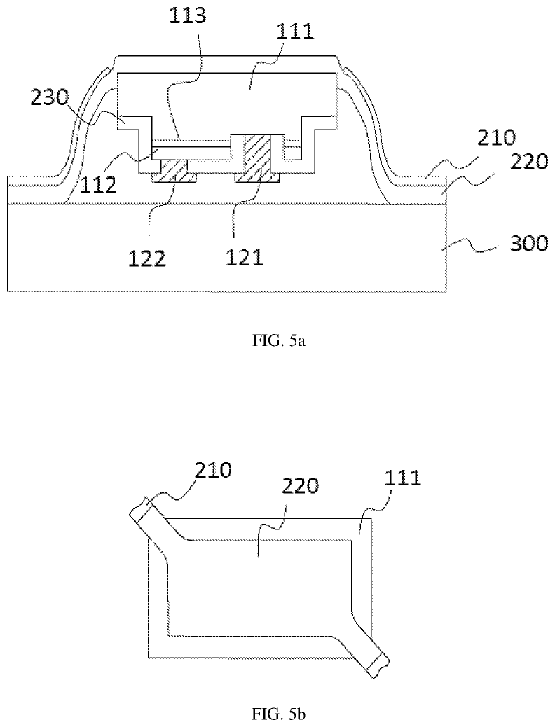

As shown in FIGS. 5a and 5b, in an embodiment 5 of the disclosure, its difference from the embodiment 4 is that the first dielectric layer 210 is removed more from the support structure 200. On the horizontal projection plane, the first dielectric layer 210 is disposed outside the main body 100, which is used to control a distance between the fracture surface and the main body 100, and avoid the first dielectric layer 210 remaining on the first surface of the body, and the first surface is a preset light-emitting surface in the embodiment, so as to avoid affecting a light type of the product.

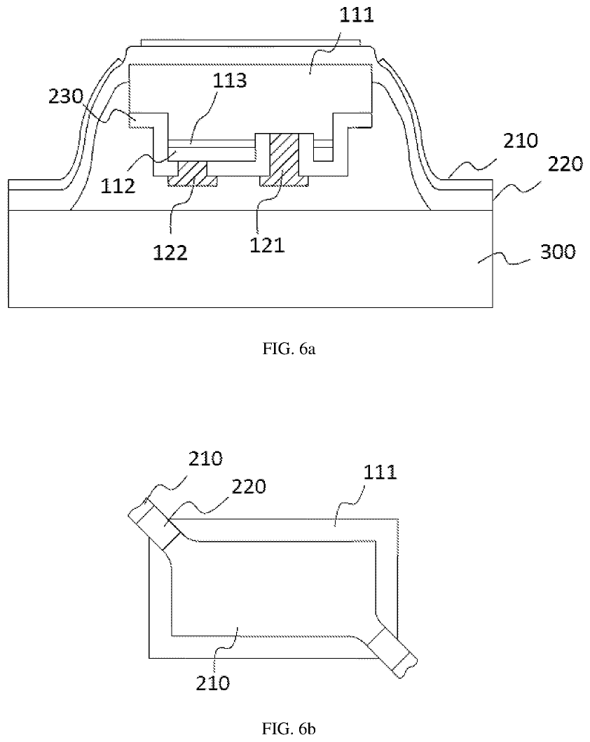

As shown in FIGS. 6a and 6b, in an embodiment 6 of the disclosure, its difference from the embodiment 5 is that a removal amount of the first dielectric layer 210 is reduced, a part of the first dielectric layer 210 above the main body 100 is reserved, and an annular groove is defined on the surface of the first dielectric layer 210.

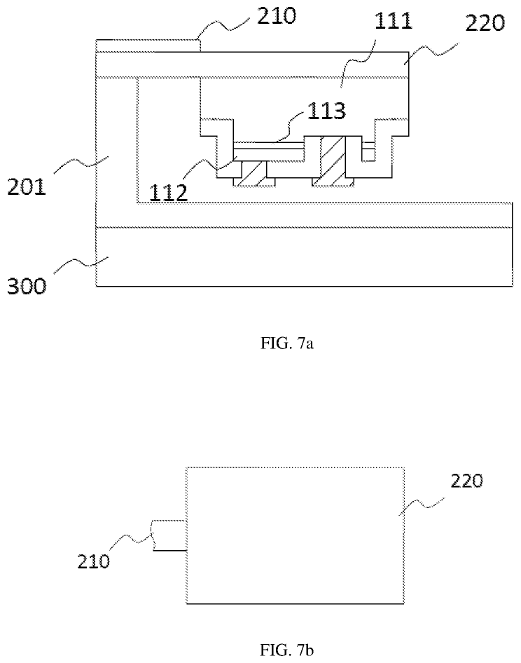

As shown in FIGS. 7a and 7b, an embodiment 7 of the disclosure provides a micro light-emitting assembly, and the micro light-emitting assembly includes a main body 100 with a semiconductor layer sequence, that is, a main body 100 of a micro light-emitting diode for emitting light. The main body 100 is connected to a substrate 300 through a support structure 200. The semiconductor layer sequence includes: a first semiconductor layer 111, a second semiconductor layer 112 and an active layer disposed between the first semiconductor layer 111 and the second semiconductor layer 112.

In the embodiment, as shown in the schematic sectional structural diagram, the support structure 200 at least includes: a first dielectric layer 210 and a second dielectric layer 220. The second dielectric layer 220 is disposed on an upper surface of the semiconductor layer sequence or the main body 100, or covers the upper surface of the semiconductor layer sequence or the main body 100, and the first dielectric layer 210 covers a surface of the second dielectric layer 220.

A thickness of the second dielectric layer 220 is 1.5 to 10 times that of the first dielectric layer 210. The thin first dielectric layer 210 is mainly used to eliminate stress in the process, and avoid rupture of the support structure 200 caused by stress release during the bonding process. The second dielectric layer 220 is used for a bridge connection between the chiplets and the substrate 300 during transferring. The thickness of the second dielectric layer 220 is significantly larger than that of the first dielectric layer 210, the materials of the first dielectric layer 210 and the second dielectric layer 220 are different, and film-forming stresses of the first dielectric layer 210 and the second dielectric layer 220 are different, thus, stress control difficulty of the support structure 200 is decreased.

In the embodiment, a material of the first dielectric layer 210 is silicon oxide, the first dielectric layer 210 is connected to the semiconductor layer sequence of the main body 100, and a material of the second dielectric layer 220 is silicon nitride. In some embodiments, the first dielectric layer 210 and/or the second dielectric layer 220 can extend downwards along an upper surface of the main body 100 of the micro light-emitting diode, and cover a side and/or a bottom of the main body 100. In the embodiment, a part of the first dielectric layer 210 is removed, the second dielectric layer 220 is exposed, so as to improve yield during transferring. A first electrode 121 and a second electrode 122 are exposed from the bottom of the first dielectric layer 210 and/or the second dielectric layer 220.

In the embodiment, the first dielectric layer 210 and/or the second dielectric layer 220 can be disposed on two sides of the main body 100, and can be also disposed on a single side of the main body 100.

In the embodiment, the support structure 200 includes: a fixed anchor 201. A material of the fixed anchor 201 is rubber material, inorganic medium or metal, specifically, the rubber material is used as the material of the fixed anchor 201. The fixed anchor 201 is directly disposed on the substrate 300, an end of the first dielectric layer 210 and/or the second dielectric layer 220 is disposed on the fixed anchor 201, and the first dielectric layer 210 and/or the second dielectric layer 220 are indirectly connected to the substrate 300 through the fixed anchor 201.

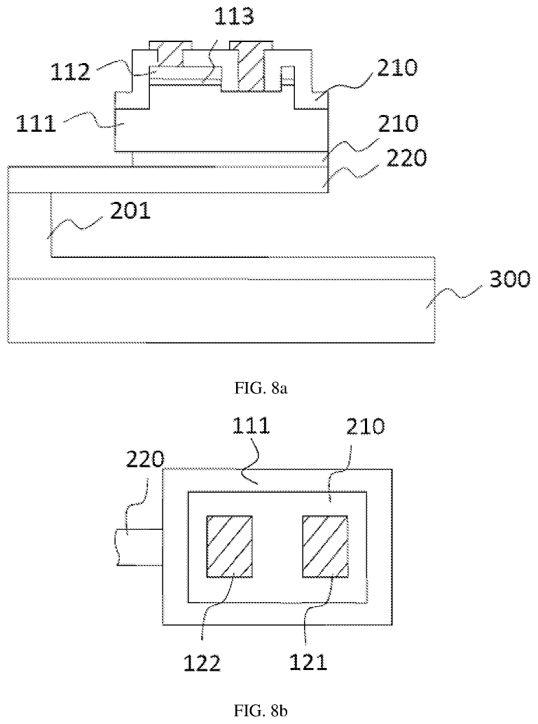

As shown in FIGS. 8a and 8b, an embodiment 8 of the disclosure provides a micro light-emitting assembly, and the micro light-emitting assembly includes a support structure 200. In the schematic sectional structural diagram, the support structure 200 at least includes a first dielectric layer 210 and a second dielectric layer 220. The first dielectric layer 210 is disposed on a lower surface of a semiconductor layer sequence or a main body 100, and the second dielectric layer 220 covers a lower surface of the first dielectric layer 210. The second dielectric layer 220 extends from the lower surface of the first dielectric layer 210 to a substrate 300, and is directly or indirectly connected to the substrate 300. A part of the support structure 200 exposed from the lower surface of the semiconductor layer sequence or the main body 100 is the second dielectric layer 220.

A thickness of the second dielectric layer 220 is 1.5 to 10 times that of the first dielectric layer 210. The thin first dielectric layer 210 is mainly used to eliminate stress in the process, and avoid rupture of the support structure 200 caused by stress release during the bonding process. The second dielectric layer 220 is used for a bridge connection between the core particles and the substrate 300 during transferring. The thickness of the second dielectric layer 220 is significantly larger than that of the first dielectric layer, the materials of the first dielectric layer 210 and the second dielectric layer 220 are different, and film-forming stresses of the first dielectric layer 210 and the second dielectric layer 220 are different, thus, stress control difficulty of the support structure 200 is decreased.

In the embodiment, a material of the first dielectric layer 210 is silicon oxide, the first dielectric layer 210 is connected to the semiconductor layer sequence of the main body 100, and a material of the second dielectric layer 220 is silicon nitride.

In the embodiment, the first dielectric layer 210 and/or the second dielectric layer 220 can be disposed on two sides of the main body 100, and can be also disposed on a single side of the main body 100. On the horizontal projection plane, a projection of the first dielectric layer 210 is in a projection of the main body 100, and a distance between the first dielectric layer 210 and an edge of the main body 100 is not larger than 0.2 μm.

In the embodiment, the support structure 200 includes: a fixed anchor 201. A material of the fixed anchor 201 is rubber material, inorganic medium or metal, specifically, the rubber material is used as the material of the fixed anchor 201. The fixed anchor 201 is directly disposed on the substrate 300, an end of the first dielectric layer 210 and/or the second dielectric layer 220 is disposed on the fixed anchor 201, and the first dielectric layer 210 and/or the second dielectric layer 220 are indirectly connected to the substrate 300 through the fixed anchor 201.

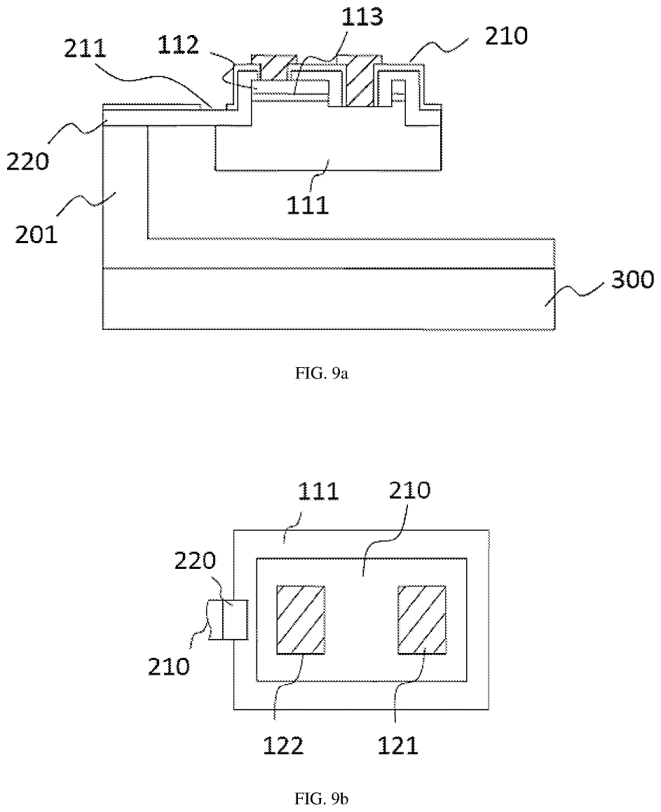

As shown in FIGS. 9a and 9b, in an embodiment 9 of the disclosure, a part of the exposed first dielectric layer 210 can be reserved, for example, the first dielectric layer 210 defines a through groove 211. The through groove 211 can be a groove or a hole, which can achieve exposing the second dielectric layer 220 from the through groove 211. In the embodiment, the through groove 211 is defined around the semiconductor layer sequence, especially, the through groove 211 can be defined above an edge of the first semiconductor layer 111.

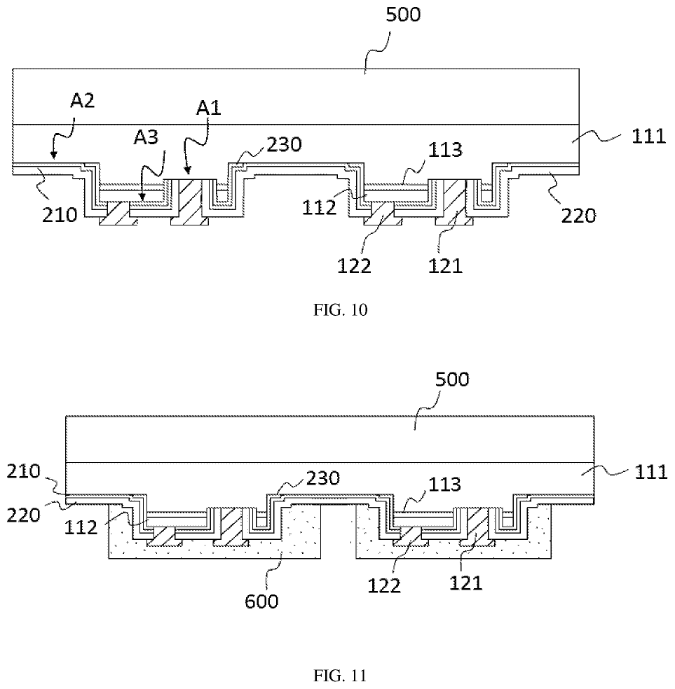

As shown in FIGS. 10 to 14, an embodiment 10 of the disclosure provides a mass transfer method of a micro light-emitting diode, and the mass transfer method includes the following steps 1-4.

As shown in FIG. 10, in step 1, a growth substrate 500 is provided, and a semiconductor layer sequence is prepared on the growth substrate 500. The semiconductor layer sequence includes: a first semiconductor layer 111, a second semiconductor layer 112 and an active layer 113 disposed between the first semiconductor layer 111 and the second semiconductor layer 112.

The second semiconductor layer 112 and the active layer 113 are locally removed by patterning to expose the first semiconductor layer 111, a first platform A1 and a second platform A2 constituted by the first semiconductor layer 111, and an epitaxial pattern of a third platform A3 constituted by the second semiconductor layer 112 are prepared on the semiconductor layer sequence, and a first dielectric layer 210 and a second dielectric layer 220 cover the semiconductor layer sequence, sequentially. In the embodiment, a third dielectric layer 230 can be disposed between the first dielectric layer 210 and the semiconductor layer sequence, and the first dielectric layer 210 covers a side of the third dielectric layer 230.

On the first platform A1 and the third platform A3, the first dielectric layer 210, the second dielectric layer 220 and the third dielectric layer 230 define openings, a first electrode 121 is prepared on the opening of the first platform A1, a second electrode 122 is prepared on the opening of the third platform A3, and a first wafer is prepared by the above process.

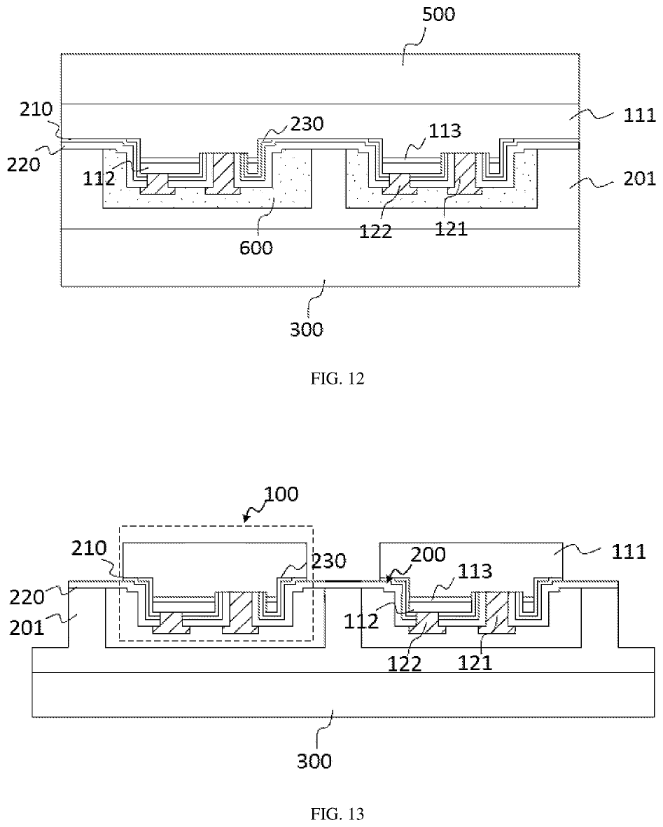

As shown in FIGS. 11 and 12, in step 2, a sacrificial bonding layer 600, a fixed anchor 201 and a substrate 300 are covered on a surface of the first wafer. A material of the sacrificial bonding layer 600 is a removable metal material. Specifically, the sacrificial bonding layer 600 and the substrate 300 are covered on a surface of the second dielectric layer 220, and a second wafer is prepared by the above process.

As shown in FIG. 13, in step 3, the growth substrate 500 is stripped, and a part of the semiconductor layer sequence is removed. In the embodiment, a part of the first semiconductor layer 111 is removed, and the first dielectric layer 210 is exposed, to thereby form multiple separated micro light-emitting diode bodies, and then the exposed first dielectric layer 210 is removed. In some implementation methods of the embodiment, the first dielectric layer 210 can be further removed by etching, that is, the first dielectric layer 210 extends along an outer edge of the main body 100, and a distance between the first dielectric layer 210 and the outer edge of the main body 100 is not larger than 0.2 μm.

The sacrificial bonding layer 600 is removed to form a support structure 200 including the second dielectric layer 220, and the support structure 200 includes the first dielectric layer 210 and the second dielectric layer 220. The micro light-emitting diode is indirectly connected to the substrate 300 through a connection rubber material (i.e., the fixed anchor) of the support structure 200.

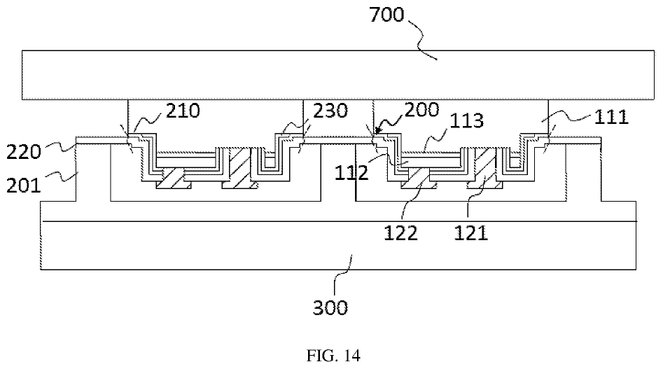

As shown in FIG. 14, in step 4, an embossing 700 is used for mass transfer the micro light-emitting diodes. Since the first dielectric layer 210 is shorter than the second dielectric layer 220, the support structure 200 is fractured on an edge of the first dielectric layer 210 proximate to the main body 100 during the embossing process. A dashed line in FIG. 14 represents a pre fractured surface, and a residue of the support structure 200 on the micro light-emitting diode is reduced as much as possible.

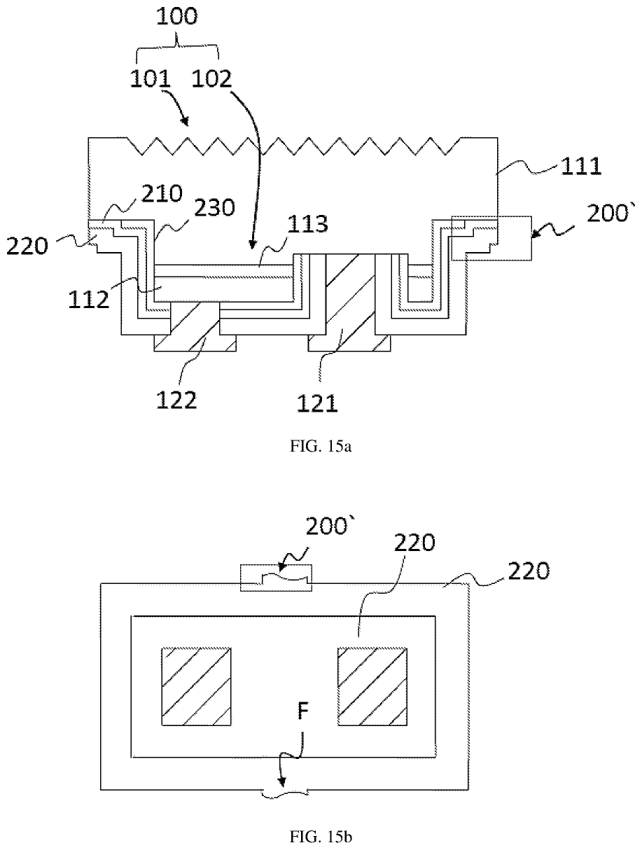

As shown in FIGS. 15a and 15b, an embodiment 11 of the disclosure provides a micro light-emitting diode, and the micro light-emitting diode includes: a semiconductor layer sequence, a first electrode 121, a second electrode 122 and a residual support structure 200′. The semiconductor layer sequence at least includes: a first semiconductor layer 111, a second semiconductor layer 112 and an active layer 113 disposed between the first semiconductor layer 111 and the second semiconductor layer 112. The semiconductor layer sequence is divided into a first part 101 and a second part 102, a projection of the first part 101 on a horizontal plane is larger than that of the second part 102 on the horizontal plane, the first part 101 is disposed above the second part 102, and a lower surface of the first part 101 is exposed from the second part 102.

The first electrode 121 is electrically connected to first semiconductor layer 111, and the second electrode 122 is electrically connected to the second semiconductor layer 112.

The residual support structure 200′ is disposed on the lower surface of the first part 101, and an end of the residual support structure 200′ facing away from the semiconductor layer sequence has a fracture surface.

The residual support structure 200′ at least includes: a first dielectric layer 210 and a second dielectric layer 220. A material of the first dielectric layer 210 is different from a material of the second dielectric layer 220, and the first dielectric layer 210 is disposed between the second dielectric layer 220 and the semiconductor layer sequence. In the embodiment, the first dielectric layer 210 covers a surface of the first semiconductor layer 111, and the second dielectric layer 220 covers a surface of the first dielectric layer 210. A thickness of the second dielectric layer 220 is 1.5 to 10 times that of the first dielectric layer 210. The material of the first dielectric layer 210 is silicon oxide, and the material of the second dielectric layer 220 is silicon nitride. The thickness of the first dielectric layer is in a range of 0.1 to 0.5 μm, and the thickness of the second dielectric layer 220 is in a range of 0.15 to 0.3 μm, 0.3 to 0.8 μm, or 0.8 to 2 μm. In the embodiment, each of the first dielectric layer 210 and the second dielectric layer 220 of the residual support structure 200′ is a single dielectric layer.

A third dielectric layer 230 is at least disposed between the first dielectric layer 210 and the main body 100. The third dielectric layer 230 is an insulation reflective layer, and a material of the third dielectric layer 230 includes titanium oxide, for example, the third dielectric layer 230 is a stack of dielectric layers. A side of the third dielectric layer 230 facing away from the main body 100 and a side of the third dielectric layer 230 proximate to an edge of the main body 100 are provided with the first dielectric layer 210. In the embodiment, a surface of the third dielectric layer 230 is provided with the first dielectric layer 210 and the second dielectric layer 220, sequentially. A distance between the third dielectric layer 230 and the edge of the main body 100 is not smaller than 0.5 μm. In the embodiment, a total thickness of the first dielectric layer 210 and/or the second dielectric layer 220 covering the third dielectric layer 230 is not smaller than 0.5 μm, especially near the edge of the first part 101 of the main body 100, the total thickness of the first dielectric layer 210 and/or the second dielectric layer 220 on the side of the third dielectric layer 230 is not smaller than 0.5 μm. The third dielectric layer 230 is disposed below the first part 101 or the second part 102, to prevent etching fluid from flowing along the side wall of the first part 101 towards the third dielectric layer 230 when roughening or patterning on the first surface. Further, the first dielectric layer 210 and/or the second dielectric layer 220 can be used to construct protection, to prevent the etching fluid from damaging the more active third dielectric layer 230.

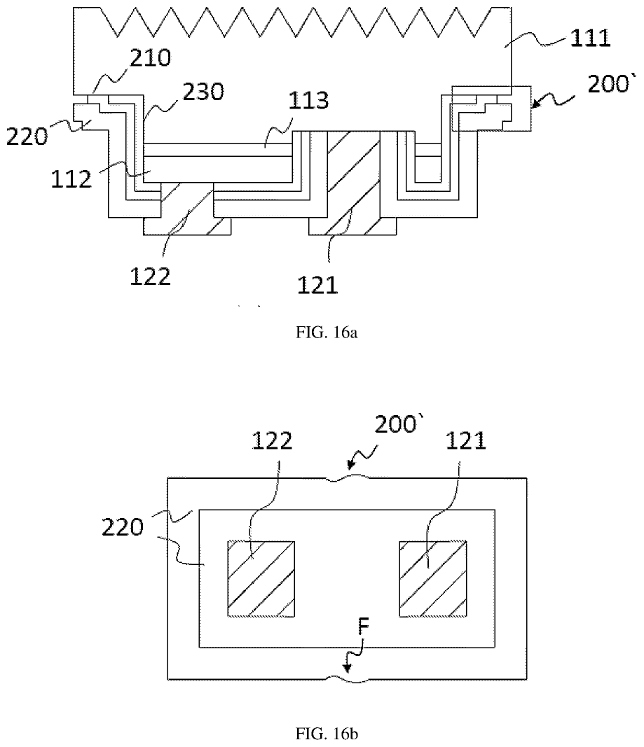

As shown in FIGS. 16a and 16b, in an embodiment 12 of the disclosure, its difference from the embodiment 11 is that in the edge of the main body 100, the first dielectric layer 210 and the second dielectric layer 220 extend outward, the first dielectric layer 210 partially shrinks relative to the second dielectric layer 220, and a length of the first dielectric layer 210 is shorter than a length of the second dielectric layer 220. At least a part of the first dielectric layer 210 is not more than 0.2 μm away from the outer edge of the main body 100, and an edge of the second dielectric layer 220 proximate to the main body 100 has a fracture surface.

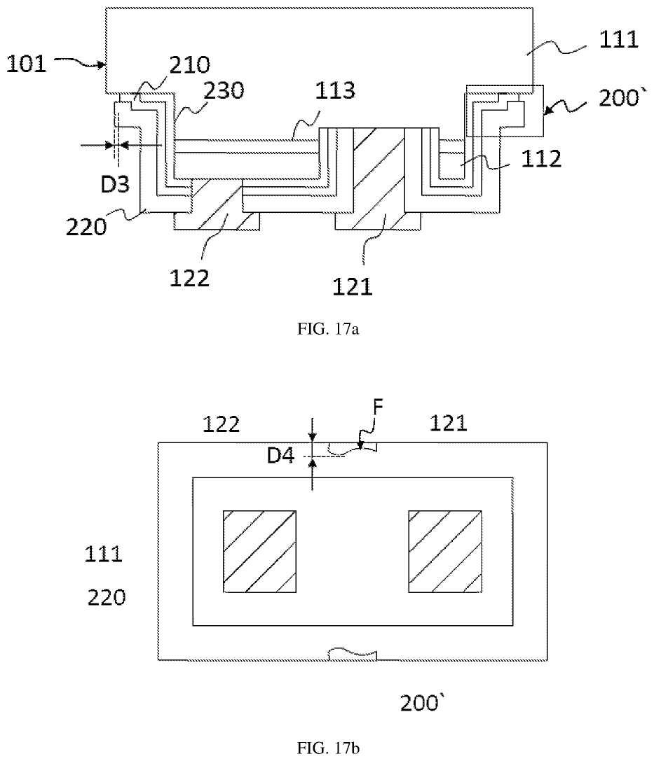

As shown in FIGS. 17a and 17b, in some embodiments, a distance D3 between the fracture surface F and the first dielectric layer 210 is not smaller than 0.2 μm, and on the horizontal projection plane, the fracture surface F is located within a projection of the semiconductor layer sequence or the main body 100, and a distance D4 between an end surface of the second dielectric layer 220 on the fracture surface and the edge of the main body 100 is not smaller than 0.2 μm. In the embodiment, the first dielectric layer 210 and the second dielectric layer 220 can fully or partially cover the exposed part of the bottom surface of the first part 101.

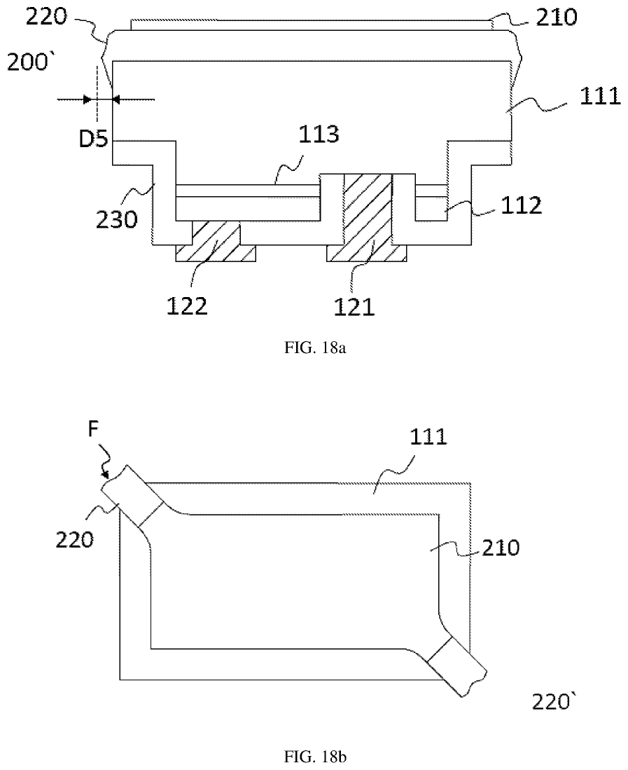

As shown in FIGS. 18a and 18b, an embodiment 13 of the disclosure provides a micro light-emitting diode, and the micro light-emitting diode includes: a semiconductor layer sequence. The semiconductor layer sequence at least includes a first semiconductor layer 111, a second semiconductor layer 112 and an active layer 113 disposed between the first semiconductor layer 111 and the second semiconductor layer 112. A fracture surface of the residual support structure 200′ is located on a side wall of the semiconductor layer sequence, and a distance D5 between the fracture surface F and an edge of a main body 100 is not larger than 0.5 μm. A first dielectric layer 210 is disposed above the first semiconductor layer 111, and a second dielectric layer 220 is disposed between the first dielectric layer 220 and the first semiconductor layer 111. The first dielectric layer 210 and the second dielectric layer 220 extend outward from an inside of the first semiconductor layer 111 to constitute the residual support structure 200′, and at least on the edge of the first semiconductor layer 111, an area of the first dielectric layer 210 is smaller than that of the second dielectric layer 220. In some embodiments, on the residual support structure 200′, a distance between an edge of the first dielectric layer 210 and an edge of the second dielectric layer 220 is not larger than 5 μm.

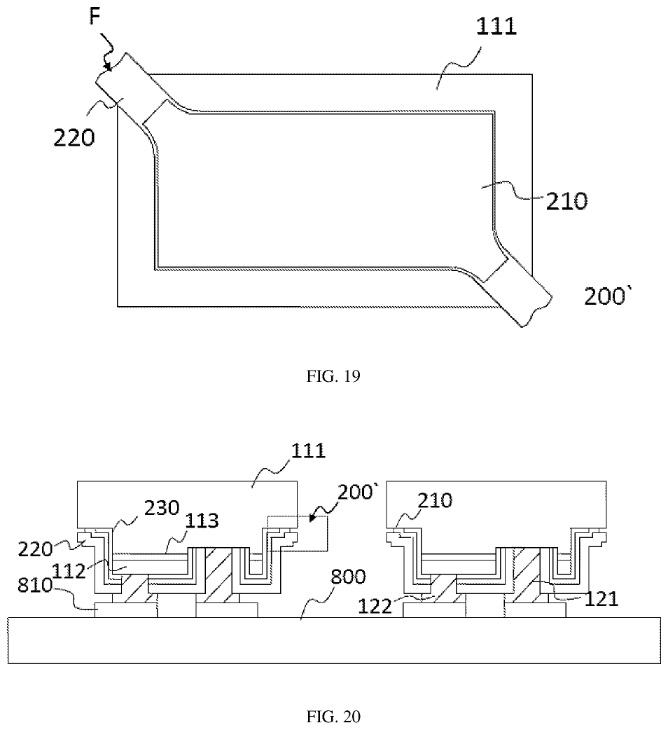

As shown in FIG. 19, in some embodiments, the first dielectric layer 210 located on a top surface of the first semiconductor layer 111 completely covers the second dielectric layer 220, the area of the first dielectric layer 210 is smaller than that of the second dielectric layer 220, and a side wall of the micro light-emitting diode is only provided with a single second dielectric layer 220.

As shown in FIG. 20, an embodiment 14 of the disclosure provides a display device, and the display device includes: a bracket 800, a circuit board 810 and the micro light-emitting diodes prepared in the above embodiments.

The embodiments of the disclosure are merely a description the disclosure, not a limitation of the disclosure. Those skilled in the art may make modifications to the embodiments as needed after reading the specification, but as long as it falls within a scope of the claims of the disclosure, it is protected by patent law.

What is claimed is:

1. A micro light-emitting assembly, comprising: a substrate, a main body with a semiconductor layer sequence, and a support structure; wherein the main body is fixed on the substrate through the support structure;
wherein the support structure comprises: a first dielectric layer and a second dielectric layer;
and a material of the first dielectric layer is different from a material of the second dielectric layer, the second dielectric layer is configured to connect the support structure and the main body, and the first dielectric layer is disposed on a surface of the second dielectric layer;
wherein a gap is defined between the main body and an upper surface of the substrate; and
wherein a thickness of the second dielectric layer is larger than a thickness of the first dielectric layer.

2. The micro light-emitting assembly as claimed in claim 1, wherein the thickness of the second dielectric layer is 1.5 to 10 times the thickness of the first dielectric layer.

3. The micro light-emitting assembly as claimed in claim 1, wherein the second dielectric layer is disposed on the main body, and at least a part of the first dielectric layer covers a surface of the second dielectric layer facing away from the main body.

4. The micro light-emitting assembly as claimed in claim 1, wherein the first dielectric layer is disposed on the main body, and at least a part of the second dielectric layer covers a surface of the first dielectric layer facing away from the main body.

5. The micro light-emitting assembly as claimed in claim 1, wherein the material of the first dielectric layer is silicon oxide, the first dielectric layer is connected to the semiconductor layer sequence of the main body, and the material of the second dielectric layer is silicon nitride;
the thickness of the first dielectric layer is in a range of 0.1 to 0.5 microns (μm); the thickness of the second dielectric layer is in a range of 0.15 to 0.3 μm, 0.3 to 0.8 μm, or 0.8 to 2 μm; widths of the first dielectric layer and the second dielectric layer are in a range of 1 to 20 μm; and each of the first dielectric layer and the second dielectric layer in the support structure is a single dielectric layer.

6. The micro light-emitting assembly as claimed in claim 1, wherein the semiconductor layer sequence at least comprises: a first semiconductor layer, an active layer and a second semiconductor layer; the main body comprises: a first part facing away from the substrate and a second part proximate to the substrate; a projection of the first part on a horizontal plane is larger than a projection of the second part on the horizontal plane; the first part at least comprises the first semiconductor layer, and the second part at least comprises the active layer and the second semiconductor layer; and a side wall of the second part is provided with at least one of the first dielectric layer and the second dielectric layer thereon.

7. The micro light-emitting assembly as claimed in claim 1, wherein the support structure comprises: a fixed anchor; a material of the fixed anchor is rubber material, inorganic medium or metal; and the second dielectric layer is connected between the first dielectric layer and the fixed anchor, and the second dielectric layer is connected to the substrate through the fixed anchor.

8. The micro light-emitting assembly as claimed in claim 1, wherein the second dielectric layer is exposed from the first dielectric layer, and the semiconductor layer sequence of the main body is fixed on the substrate through the second dielectric layer.

9. The micro light-emitting assembly as claimed in claim 8, wherein the first dielectric layer defines a through groove, the second dielectric layer is exposed from the through groove, and the through groove is defined around the semiconductor layer sequence.

10. The micro light-emitting assembly as claimed in claim 1, wherein a side of the main body proximate to the substrate is provided with a third dielectric layer; a material of the third dielectric layer comprises: titanium oxide; and the third dielectric layer is disposed between the main body and the first dielectric layer, and the first dielectric layer and the second dielectric layer cover a side of the third dielectric layer, sequentially.

11. A micro light-emitting assembly, comprising:
a main body with a semiconductor layer sequence; and
a first dielectric layer and a second dielectric layer; wherein a material of the first dielectric layer is different from a material of the second dielectric layer; the first dielectric layer is disposed between the second dielectric layer and the semiconductor layer sequence, and is disposed on a surface of the second dielectric layer; and
wherein a thickness of the second dielectric layer is larger than a thickness of the first dielectric layer.

12. A micro light-emitting diode, comprising:
a semiconductor layer sequence, at least comprising: a first semiconductor layer, a second semiconductor layer and an active layer disposed between the first semiconductor layer and the second semiconductor layer; wherein the semiconductor layer sequence is divided into a first part and a second part; a projection of the first part on a horizontal plane is larger than a projection of the second part on the horizontal plane; and the first part is disposed above the second part, and a lower surface of the first part is exposed from the second part;
a first electrode, electrically connected to the first semiconductor layer;
a second electrode, electrically connected to the second semiconductor layer;
a residual support structure, disposed on a surface of the first part; and
wherein the residual support structure at least comprises: a first dielectric layer and a second dielectric layer; a material of the first dielectric layer is different from a material of the second dielectric layer, and a thickness of the second dielectric layer is 1.5 to 10 times a thickness of the first dielectric layer.

13. The micro light-emitting diode as claimed in claim 12, wherein the first part at least comprises: the first semiconductor layer, and the second part at least comprises: the active layer and the second semiconductor layer; and a side wall of the second part is provided with at least one of the first dielectric layer and the second dielectric layer thereon.

14. The micro light-emitting diode as claimed in claim 12, wherein a surface of the first semiconductor layer facing away from the second semiconductor layer is provided with a coarse structure.

15. The micro light-emitting diode as claimed in claim 14, wherein a surface of the second semiconductor layer facing away from the first semiconductor layer is provided with a third dielectric layer; the first dielectric layer is disposed between the second dielectric layer and the semiconductor layer sequence, the third dielectric layer is disposed between the semiconductor layer sequence and the first dielectric layer, and the first dielectric layer and the second dielectric layer cover a side of the third dielectric layer, sequentially.

16. The micro light-emitting diode as claimed in claim 12, wherein the material of the first dielectric layer is silicon oxide, the material of the second dielectric layer is silicon nitride, and each of the first dielectric layer and the second dielectric layer is a single dielectric layer.

17. The micro light-emitting diode as claimed in claim 12, wherein the first dielectric layer is disposed on a surface of the first part proximate to the second part, and the second dielectric layer is disposed on a side of the first dielectric layer facing away from the first part; and the first dielectric layer is partially retracted relative to the second dielectric layer, and a length of the first dielectric layer is shorter than a length of the second dielectric layer.

18. The micro light-emitting diode as claimed in claim 12, wherein the first dielectric layer is disposed on a surface of the first semiconductor layer facing away from the second dielectric layer, and the second dielectric layer is disposed between the first dielectric layer and the first semiconductor layer; and an area of the first dielectric layer is smaller than an area of the second dielectric layer, and a side wall of the micro light-emitting diode is provided with a single layer of the second dielectric layer.

19. The micro light-emitting diode as claimed in claim 12, wherein an end of the residual support structure facing away from the semiconductor layer sequence defines a fracture surface.

20. A display device, comprising: a bracket, a circuit board and the micro light-emitting diode as claimed in claim 12.
